(19) United States
(12) Patent Application Publication
(10) Pub. No.: US 2014/0041206 A1
(43) Pub. Date: Feb. 13, 2014

(54) METHOD FOR REPAIRING VIA OF CIRCUIT BOARD

(71) Applicant: SAMSUNG ELECTRO-MECHANICS CO., LTD., Suwon-si (KR)

(72) Inventors: Hye Jin CHO, Suwon-si (KR); Hyo Jin YOON, Suwon-si (KR); Suk Jin HAM, Suwon-si (KR); Sung Hee LIM, Suwon-si (KR); Seong Chan PARK, Suwon-si (KR); Ji Eun JEON, Suwon-si (KR)

(73) Assignee: SAMSUNG ELECTRO-MECHANICS CO., LTD., Suwon-si (KR)

(21) Appl. No.: 13/843,640

(22) Filed: Mar. 15, 2013

(30) Foreign Application Priority Data
Aug. 10, 2012 (KR) 10-2012-0087912

(51) Int. Cl. H05K 3/00

(52) U.S. Cl. CPC H05K 3/0094
USPC 29/593; 29/829

(57) ABSTRACT

Disclosed herein is a method for repairing a via in which a dimple phenomenon occurs, in the case in which a dimple error occurs at the time of a process of forming the via used for electrically connecting between layers of a multi-layers circuit board. The method for repairing a via according to an exemplary embodiment of the present invention includes judging whether or not a dimple error occurs in a via; and repairing the via in which the dimple error occurs.

### CROSS REFERENCE(S) TO RELATED APPLICATIONS

This application claims the benefit under 35 U.S.C. Section 119 of Korean Patent Application Serial No. 10-2012-0087912, entitled “Method for Reparing Via of Circuit Board” filed on Aug. 10, 2012, which is hereby incorporated by reference in its entirety into this application.

### BACKGROUND OF THE INVENTION

1. Technical Field

The present invention relates to a method for repairing a via of a circuit board, and more particularly, to a method for repairing a via in which a dimple error occurs.

2. Description of the Related Art

In general, a print circuit board has a stacked structure in which a plurality of sheets are stacked and uses a conductive via (hereinafter, referred to as ‘a via’) in order to electrically connect between layers of circuit patterns formed on the respective sheets. The via as described above is formed by performing an electrical copper plating process or a chemical copper plating process on the circuit board. However, due to various causes such as a problem in the process, aging of liquid, and the like, a so called dimple phenomenon in which a via hole of the circuit board is not fully filled at the time of processing occurs. The via in which the dimple phenomenon occurs has a shape in which a central portion thereof is convexly depressed.

When the dimple phenomenon occurs in the via as described above, the circuit board should be discarded. Particularly, since all the circuit boards should be discarded even though the dimple phenomenon occurs in only some of the vias of the circuit board, when the dimple phenomenon occurs in the vias, productivity is significantly decreased. Further, since a process of forming the vias is performed after forming a copper wire, in the case in which the dimple error occurs in the plating process, production loss is significantly increased.

### RELATED ART DOCUMENT

### Patent Document

(Patent Document 1) Korean Patent Laid-Open Publication No. 10-2011-0002639

### SUMMARY OF THE INVENTION

An object of the present invention is to provide a method for repairing a via capable of improving production efficiency of a printed circuit board.

Another object of the present invention is to provide a method for repairing a via of a circuit board capable of efficiently repairing a via in which a dimple phenomenon occurs.

According to an exemplary embodiment of the present invention, there is provided a method for repairing a via of a circuit board, the method including: judging whether or not a dimple error occurs in a via; and repairing the via in which the dimple error occurs.

The judging of whether or not the dimple error occurs in the via may include: measuring a thickness of the via; and judging whether or not the thickness of the via satisfies a preset via thickness.

The judging of whether or not the dimple error occurs in the via may include judging whether or not a thickness of the via is more than 70% to less than 80% of an ideal thickness of the via.

The repairing of the via in which the dimple error occurs may include: performing an inkjet printing process on the via using a nano paste material; and performing a firing process on the via.

The repairing of the via in which the dimple error occurs may include: performing an inkjet printing process on the via using an organo metal, and performing a firing process on the via.

According to another exemplary embodiment of the present invention, there is provided a method for repairing a via of a circuit, the method including: judging whether or not a dimple error occurs in a via; selecting a detailed repair method for the via in which the dimple error occurs; and repairing the via in which the dimple error occurs using the selected detailed repair method.

The judging of whether or not the dimple error occurs in the via may include: measuring a thickness of the via, and judging whether or not the thickness of the via satisfies a preset via thickness.

The judging of whether or not the dimple error occurs in the via may include judging whether or not a thickness of the via is more than 70% to less than 80% of an ideal thickness of the via.

The selecting of the detailed repair method may include selecting one of a repair method using a nano paste material and a repair method using an organic metal material.

The selecting of the detailed repair method may select the repair method using a nano paste material in the case in which a thickness of the via to be filled in the via in which the dimple phenomenon occurs is more than 5 μm to less than 10 μm, and select the repair method using an organic metal material in the case in which the thickness of the via to be filled into the via in which the dimple phenomenon occurs is less than 5 μm.

The repairing of the via may include: filling a filling material in the via in which the dimple phenomenon occurs; and performing a firing process on the via using a reducing and sintering method under an organic acid atmosphere.

The repairing of the via in which the dimple error occurs may include performing an inkjet printing process.

### BRIEF DESCRIPTION OF THE DRAWINGS

FIG. 1 is a flow chart showing a method for repairing a via of a circuit board according to an exemplary embodiment of the present invention.

FIGS. 2 to 4 are views for describing a process for repairing a via of a circuit board according to the exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Further, the exemplary embodiments described in the specification will be described with reference to cross-sectional views and/or plan views that are ideal exemplification figures. In drawings, the thickness of layers and regions is exaggerated for efficient description of technical contents. Therefore, exemplified forms may be changed by manufacturing technologies and/or tolerance. Therefore, the exemplary embodiments of the present invention are not limited to specific forms but may include the change in forms generated according to the manufacturing processes For example, an etching region vertically shown may be rounded or may have a predetermined curvature.

Hereinafter, a method for repairing a via of a circuit board according to an exemplary embodiment of the present invention will be described in detail with reference to the accompany drawings.

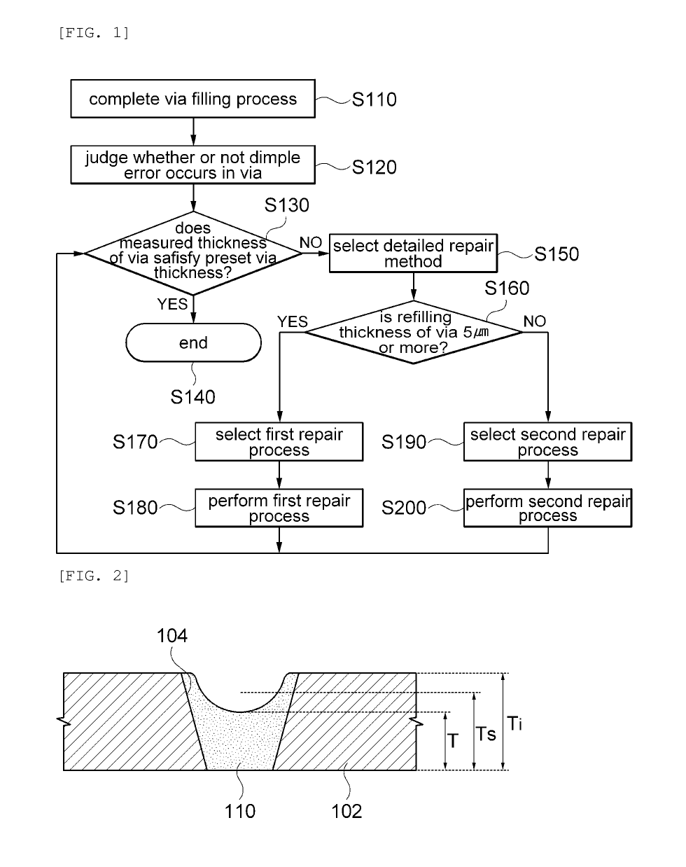

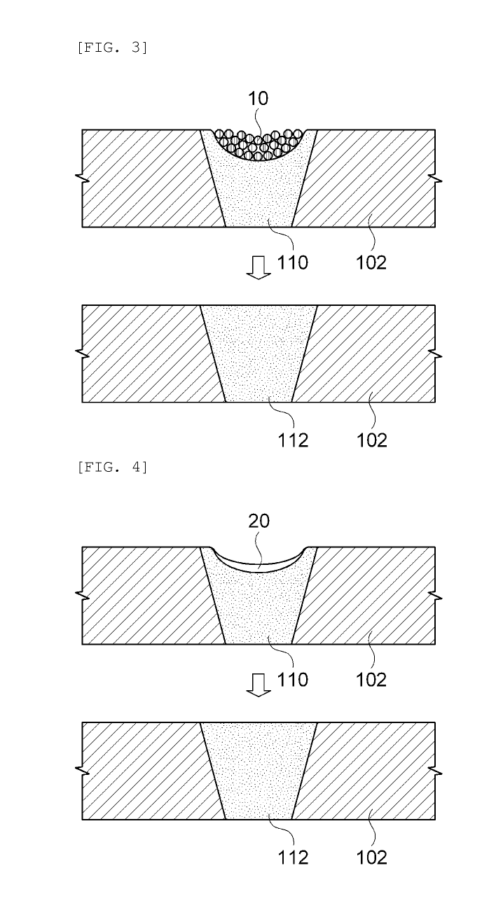

FIG. 1 is a flow chart showing a method for repairing a via of a circuit board according to an exemplary embodiment of the present invention; and FIGS. 2 to 4 are views for describing a process for repairing a via of a circuit board according to the exemplary embodiment of the present invention.

Referring to FIGS. 1 and 2, a via filling process may be completed (S110), and whether or not a dimple error occurs in a formed via 110 may be judged (S120). The via 110 may be a connector for electrically connecting between the respective layers configuring a multi-layer circuit board such as a printed circuit board (PCB). The via 110 may be a result obtained by performing a predetermined copper plating process on the circuit board 102, and the dimple error phenomenon may be a phenomenon in which since a plating layer is not fully filled in a via hole 104 of the circuit board 102 in a process of performing the copper plating process, the via 110 has a shape in which a central portion thereof is convex toward a downward direct (that is, a direction in which the via is filled).

The judging of whether or not the dimple error occurs in the via 110 may be performed in an inspection process for the circuit board 102 after completing the copper plating process. Herein, the inspection process may performed so as to collect information on a position of the via hole in which the dimple error occurs.

Then, whether or not a measured thickness of the via satisfies a preset via thickness Ts may be judged (S130). That is, the judging of whether or not the dimple error is generated in the via 110 may include measuring a thickness T of the via 110 and judging whether or not the thickness T of the via 110 satisfies a range of the preset via thickness Ts. The preset via thickness Ts may be a minimum thickness value at which the via 110 may normally function. For example, assuming that in the case in which the via 110 is ideally filled in the circuit board 102, an ideal via thickness Ti is 1, the preset via thickness Ts may be set to approximately 70% or more, more preferably, 80% or more, of the ideal via thickness Ti. That is, in the case in which the ideal via thickness Ti is 100 μm, the preset via thickness Ts may be set to 70 μm or more that is a 70% level of the ideal via thickness, more preferably, 80 μm or more that is a 80% level of the ideal via thickness. In the case in which the preset via thickness Ts is set to exceed 80% of the ideal via thickness Ti, an unnecessary repair work may be performed on the via capable of normally functioning. However, a reference value of the preset via thickness may be changed according to a diameter, a depth, a shape, and the like, of the via hole 104, and may not be limited to the above conditions.

As described above, the judging of whether or not the dimple error is generated in the via 110 may be performed by setting the preset via thickness Ts of the via 110 and then judging whether the thickness of the via 110 satisfies the preset via thickness Ts in the inspection process, and the repair work of the via 110 may be selectively performed only in the case in which the thickness T of the via 110 is thinner than the preset via thickness Ts. In the case in which the thickness T of the via 110 is thicker than the preset via thickness Ts, it may be determined that the via is normally formed, thereby terminating the inspection process (S140).

In the case in which the measured thickness T of the via 110 does not satisfy the preset via thickness Ts, it may be determined that the dimple error occurs, thereby selecting a detailed repair method (S150). The selecting of the detailed repair method may be determined according to a degree of a refilling thickness of the via 110 in which the dimple phenomenon occurs. More specifically, in the case in which the measured thickness T of the via 110 is significantly lower than the preset via thickness Ts, a repair process in which a more amount of material may be filled is performed, and in the case in which the thickness T of the via 110 is slightly lower than the preset via thickness Ts, a repair process in which a less amount of material may be filled is performed, respectively.

To this end, whether or not the refilling thickness of the via 110 is 5 μm or more may be judged (S160). For example, in the case in which the refilling thickness of the via exceeds 5 μm, that is, the preset via thickness Ts is 80 μm and the measured thickness T of the via 110 is less than 75 μm, a first repair process in which a relatively more amount of material may be filled by a single process may be selected (S170).

Referring to FIGS. 1 and 3, the selected first repair process may be performed (S180). As the first repair process, a screen printing process using a nano-paste material or an inkjet printing process may be used. Here, in the case in which the inkjet printing process is used, the via in which the error occurs may be selected and selectively repaired. Therefore, the inkjet printing process is more preferable in view of repair process efficiency than the screen printing process. More specifically, in the performing of the first repair process, preparing a Cu nano paste material 10, filling the Cu nano paste 10 in the via 110 by performing the inkjet printing process, and performing a firing process using a reducing and sintering method under an organic acid atmosphere may be sequentially performed. Here, a use amount of Cu nano paste material may be in proportion to the refilling thickness of the via 110. In order to prevent oxidation of the copper, it is preferable to perform the firing process under a reduction atmosphere and to use a formic acid as the organic acid. A reduction method using alcohol is mild and the firing process under a strong acid atmosphere may cause corrosion of other organic insulating materials. A repaired via 112 may be formed on the circuit board 102 by performing the first repair process as described above.

Meanwhile, referring to FIGS. 1 and 4, in the case in which the refilling thickness of the via is less than 5 μm, that is, the preset via thickness Ts is 80 μm and the measured thickness T of the via 110 is more than 75 μm to less than 80 μm, a second repair process in which a less amount of material may be precisely filled may selected (S190).

Then, the selected second repair process may be performed (S200). As the second repair process, the inkjet printing process using an organic metal material may be used. More specifically, in the performing of the second repair process, preparing a Cu nano paste material 20, filling the Cu nano paste 10 into the via 110 by performing the inkjet printing process, and performing a firing process using a reducing and sintering method under an organic acid atmosphere may be sequentially performed. The organic metal material may secure conductivity through thermal degradation, and it is preferable to perform the firing process under the reduction atmosphere and use the formic acid as the organic acid in order to prevent the oxidation of the copper. A reduction method using alcohol is mild and the firing process under a strong acid atmosphere may cause corrosion of other organic insulating materials. A repaired via 112 may be formed on the circuit board 102 by performing the second repair process as described above.

Meanwhile, after performing the first and second repair processes, whether or not the thickness of the repaired via 112 satisfies the preset via thickness Ts may be again judged (S130). In the case in which the thickness of the repaired via satisfies the preset via thickness Ts, the repair process is stopped. To the contrary, in the case in which the thickness of the repaired via does not satisfy the preset via thickness Ts, the repair process as described above may be again performed.

As described above, in the via repair method according to the exemplary embodiment of the present invention, the thickness of the via 110 formed through the via filling process is measured, thereby making it possible to judge whether or not the dimple phenomenon occurs and repair the via in which the dimple phenomenon occurs. Therefore, in the method for repairing a via of a circuit board according to the exemplary embodiment of the present invention, the via in which the dimple phenomenon occurs is repaired and used, thereby making it possible improve the production efficiency of the circuit board.

In the via repair method according to the exemplary embodiment of the present invention, the thickness of the via 110 formed through the via filling process is measured to repair the via in which the dimple phenomenon occurs, and the thickness of the via to be refilled is measured and the repair method is then selected according to the thickness of the via to be refilled, thereby making it possible to perform the repair process. Therefore, in the via repair method according to the exemplary embodiment of the present invention, the repair method appropriate for the via in which the dimple phenomenon occurs is selected and performed, thereby making it possible to improve the via repair process efficiency.

In addition, in the via repair method according to the exemplary embodiment of the present invention, the via in which the dimple phenomenon occurs may be repaired and the via in which the dimple phenomenon occurs may be selected and selectively repaired using the inkjet printing process. Therefore, in the via repair method according to the exemplary embodiment of the present invention, the via in which the dimple phenomenon occurs is selected and selectively repaired, thereby making it possible to improve the via repair process efficiency.

In the method for repairing a via of a circuit board according to the exemplary embodiment of the present invention, the via in which the dimple phenomenon occurs is repaired and used, thereby making it possible to improve the production efficiency of the circuit board.

In the method for repairing a via of a circuit board according to the exemplary embodiment of the present invention, the repair method appropriate for the via in which the dimple phenomenon occurs is selected and performed, thereby making it possible to improve the via repair process efficiency.

In the method for repairing a via of a circuit board according to the exemplary embodiment of the present invention, the via in which the dimple phenomenon occurs is selected and selectively repaired, thereby making it possible to improve the via repair process efficiency.

The above detailed description has illustrated the present invention. In addition, the above-mentioned description discloses only the exemplary embodiments of the present invention. Therefore, it is to be appreciated that modifications and alterations may be made by those skilled in the art without departing from the scope of the present invention disclosed in the present specification and an equivalent thereof. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A method for repairing a via of a circuit board, the method comprising:
judging whether or not a dimple error occurs in a via; and
repairing the via in which the dimple error occurs.

2. The method according to claim 1, wherein the judging of whether or not the dimple error occurs in the via includes:
measuring a thickness of the via; and
judging whether or not the thickness of the via satisfies a preset via thickness.

3. The method according to claim 1, the judging of whether or not the dimple error occurs in the via includes judging whether or not a thickness of the via is more than 70% to less than 80% of an ideal thickness of the via.

4. The method according to claim 1, wherein the repairing of the via in which the dimple error occurs includes:
performing an inkjet printing process on the via using a nano paste material; and
performing a firing process on the via.

5. The method according to claim 1, wherein the repairing of the via in which the dimple error occurs includes:
performing an inkjet printing process on the via using an organo metal, and
performing a firing process on the via.

6. A method for repairing a via of a circuit, the method comprising:
judging whether or not a dimple error occurs in a via;
selecting a detailed repair method for the via in which the dimple error occurs; and
repairing the via in which the dimple error occurs using the selected detailed repair method.

7. The method according to claim 6, wherein the judging of whether or not the dimple error occurs in the via includes:
measuring a thickness of the via, and
judging whether or not the thickness of the via satisfies a preset via thickness.

8. The method according to claim 6, wherein the judging of whether or not the dimple error occurs in the via includes judging whether or not a thickness of the via is more than 70% to less than 80% of an ideal thickness of the via.

9. The method according to claim 6, wherein the selecting of the detailed repair method includes selecting one of a repair method using a nano paste material and a repair method using an organic metal material.

10. The method according to claim 6, wherein the selecting of the detailed repair method:
selects the repair method using a nano paste material in the case in which a thickness of the via to be filled in the via in which the dimple phenomenon occurs is more than 5 μm to less than 19 μm, and selects the repair method using an organic metal material in the case in which the thickness of the via to be filled into the via in which the dimple phenomenon occurs is less than 5 μm.

11. The method according to claim 6, wherein the repairing of the via includes:
filling a filling material in the via in which the dimple phenomenon occurs; and
performing a firing process on the via using a reducing and sintering method under an organic acid atmosphere.

12. The method according to claim 6, wherein the repairing of the via in which the dimple error occurs includes performing an inkjet printing process.
